(19) United States
(12) Patent Application Publication
(10) Pub. No.: US 2026/0033372 A1
(43) Pub. Date: Jan. 29, 2026

(54) Semiconductor package having air via

(71) Applicant: RF MATERIALS CO., LTD., Ansan-si (KR)

(72) Inventors: Won Shil KANG, Seoul (KR); Jin Young JEONG, Seoul (KR); Juwan KIM, Siheung-si (KR)

(21) Appl. No.: 18/789,563

(22) Filed: Jul. 30, 2024

(30) Foreign Application Priority Data
Jul. 24, 2024 (KR) 10-2024-0097899

(51) Int. Cl. H01L 23/498; H01L 23/13; H01L 23/36

(52) U.S. Cl. CPC H01L 23/49822; H01L 23/13; H01L 23/36

(57) ABSTRACT

Proposed is a semiconductor package having air via, which can reduce RF loss and increase the frequency bandwidth by reducing dielectric loss and parasitic capacitance components of semiconductor packages by providing an air via vertically in the space between first, second, and third dielectric layers, which are sequentially stacked with a signal line pad and a ground pad, thereby improving package performance.

### CROSS REFERENCE TO RELATED APPLICATION

This application claims priority from and the benefit of Korean Patent Application No. 10-2024-0097899, filed on Jul. 24, 2024, which is hereby incorporated by reference for all purposes as if fully set forth herein.

### BACKGROUND

### Field

The present disclosure relates to a semiconductor package having air via, which can reduce RF loss and increase the frequency bandwidth by reducing dielectric loss and parasitic capacitance components of semiconductor packages by providing an air via vertically in the space between first, second, and third dielectric layers, which are sequentially stacked with a signal line pad and a ground pad, thereby improving package performance.

### Discussion of the Background

As is well known, semiconductor devices need to be electrically packaged in order for a semiconductor chip to be mounted in the required location as a component of a board or an electronic device, and the packaging has functions and roles such as interconnection, power supply, heat dissipation, and semiconductor chip protection.

One example of such semiconductor packaging is flat no-lead packages, which refer to a type of integrated circuit package with integrated pins for surface mounting and include dual-flat no-lead (DFN) and quad-flat no-lead (QFN) packages.

In the case of hermetic packages used in space-level quantum computing, low loss and high heat dissipation performance are required, and the most suitable material that can satisfy this requirement is a ceramic-based material, a representative example being alumina (Al2O3).

That is, reliability issues may arise due to the effects of contraction and expansion, and reliability problems may occur due to different linear expansion coefficients between a package and an integrated circuit (IC), and the material mainly used to prevent this is alumina (Al2O3).

Alumina has the advantage of having low dielectric loss and high heat dissipation properties, but has the disadvantage of narrowing the frequency band due to the generation of parasitic capacitance depending on the design due to its high dielectric constant. Since coefficient of thermal expansion mismatch between a package and a printed circuit board (PCB) is also an important factor, column grid array (CGA) packages may be used to compensate for this.

Flat no-lead as described above are often referred to as micro-lead frames, and quad-flat no-lead (QFN) packages can provide physical and electrical connections between encapsulated IC components and the external circuitry on a PCB.

In semiconductor packages as described above, such as lead-type packages, CGA packages, and QFN packages, dielectric loss may increase due to a dielectric provided inside, which not only increases RF loss but also reduces the frequency bandwidth due to parasitic capacitance components, resulting in package performance deterioration.

To remedy the above-described problems, there is a need for the development of technologies that can improve package performance by reducing dielectric loss and parasitic capacitance components of semiconductor packages, thereby reducing RF loss and increasing frequency bandwidth.

### SUMMARY

Accordingly, the present disclosure has been made keeping in mind the above problems occurring in the related art, and the present disclosure is intended to provide a semiconductor package having air via, which can reduce RF loss and increase the frequency bandwidth by reducing dielectric loss and parasitic capacitance components of semiconductor packages by providing an air via vertically in the space between first, second, and third dielectric layers, which are sequentially stacked with a signal line pad and a ground pad, thereby improving package performance.

The objectives of the present disclosure are not limited to those mentioned above, and other objectives not mentioned will be clearly understood by those skilled in the art from the description below.

In order to achieve the above objective, according to an embodiment of the present disclosure, there is provided a semiconductor package having air via, including: a first dielectric layer, a second dielectric layer, and a third dielectric layer that are sequentially stacked and have a signal line and a ground, wherein an air via may be provided vertically in an outer area of the signal line provided in the first dielectric layer, the second dielectric layer, and the third dielectric layer.

In addition, according to an embodiment of the present disclosure, the first dielectric layer may include: a first signal line pad provided in a lower central area of the first dielectric layer in contact with a substrate; a first ground pad provided on each side of the first signal line pad, adjacent to a castellation cavity provided vertically on outer surfaces of the first dielectric layer, the second dielectric layer, and the third dielectric layer, a second ground pad provided on a top of the first dielectric layer and in a peripheral area excluding an area where the first signal line pad is provided; a first ground via electrically connecting the first ground pad and the second ground pad; a first signal line via vertically penetrating the first dielectric layer and having a lower part thereof in contact with the first signal line pad; and a signal line alignment pad provided on top of the first signal line via.

In addition, according to an embodiment of the present disclosure, the second dielectric layer may include: a second signal line via vertically penetrating the second dielectric layer and having a lower part thereof in contact with the signal line alignment pad; a second signal line pad provided on top of the second signal line via to transmit a signal; a third ground pad provided on each side of the second signal line pad; and a second ground via electrically connecting the second ground pad and the third ground pad.

In addition, according to an embodiment of the present disclosure, the third dielectric layer is a 3-1 dielectric layer and a 3-2 dielectric layer sequentially stacked, and may include: a 4-1 ground pad provided between the 3-1 dielectric layer and the 3-2 dielectric layer, a 4-2 ground pad provided on a top of the third dielectric layer; and a third ground via vertically penetrating the 4-1 ground pad and electrically connecting the third ground pad and the 4-2 ground pad.

In addition, according to an embodiment of the present disclosure, the air via may be provided in an area on each side of the first signal line via and the second signal line via stacked with the signal line alignment pad in between by vertically penetrating the second ground pad and the third ground pad, and provided such that a lower part thereof is located in an internal area of the first dielectric layer while an upper part thereof is in contact with the 4-1 ground pad.

In addition, according to an embodiment of the present disclosure, the semiconductor package may further include a heat sink provided in contact with an inner surface of the first dielectric layer.

According to the present disclosure, by providing an air via vertically in the space between first, second, and third dielectric layers, which are sequentially stacked with a signal line pad and a ground pad, dielectric loss and parasitic capacitance components of semiconductor packages can be reduced, and thus RF loss can be reduced and the frequency bandwidth can be increased, thereby improving package performance.

Furthermore, according to the present disclosure, by forming air via in a semiconductor package, the weight of the semiconductor package can be reduced, and the inflow of external foreign substances can be blocked, effectively maintaining the performance of the semiconductor package.

### BRIEF DESCRIPTION OF THE DRAWINGS

The above and other objectives, features, and other advantages of the present disclosure will be more clearly understood from the following detailed description when taken in conjunction with the accompanying drawings, in which:

FIGS. 1 and 2 are views showing a semiconductor package having air via according to an embodiment of the present disclosure; and

FIGS. 3 to 5 are views showing the detailed configuration of a semiconductor package having air via according to an embodiment of the present disclosure.

FIG. 6 is a graph showing a frequency bandwidth of the semiconductor package shown in FIGS. 1 to 5 compared to the conventional cases.

### DETAILED DESCRIPTION

The advantages and features of embodiments of the present disclosure, and methods of achieving them, will become clear with reference to the embodiments described below in conjunction with the accompanying drawings. However, the present disclosure is not limited to the embodiments disclosed below, but may be implemented in various different forms. The embodiments are provided solely to ensure that the disclosure of the present disclosure is complete and to fully inform those skilled in the art of the scope of the invention. The present disclosure is defined only by the scope of the claims. Like reference numerals refer to like elements throughout the specification.

In describing the present disclosure, when it is determined that a detailed description of a related known configuration or function may obscure the gist of the present disclosure, the detailed description thereof will be omitted. In addition, the terms used in the specification are defined in consideration of functions in the embodiments of the present disclosure, and may vary depending on the intention of a user or operator, custom, and the like. Therefore, the terms should be interpreted based on the contents throughout the specification.

Hereinafter, embodiments of the present disclosure will be described in detail with reference to the attached drawings.

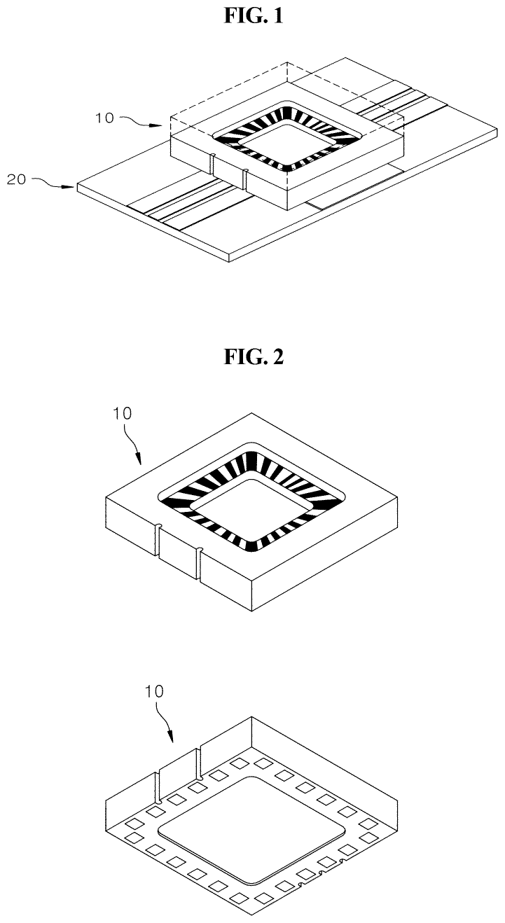

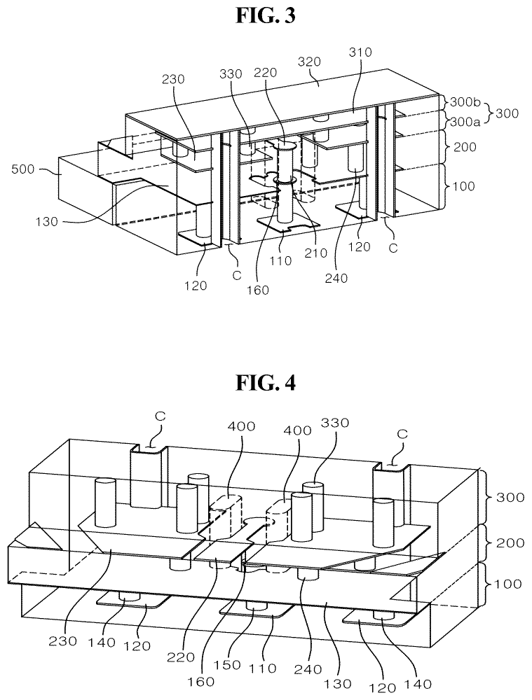

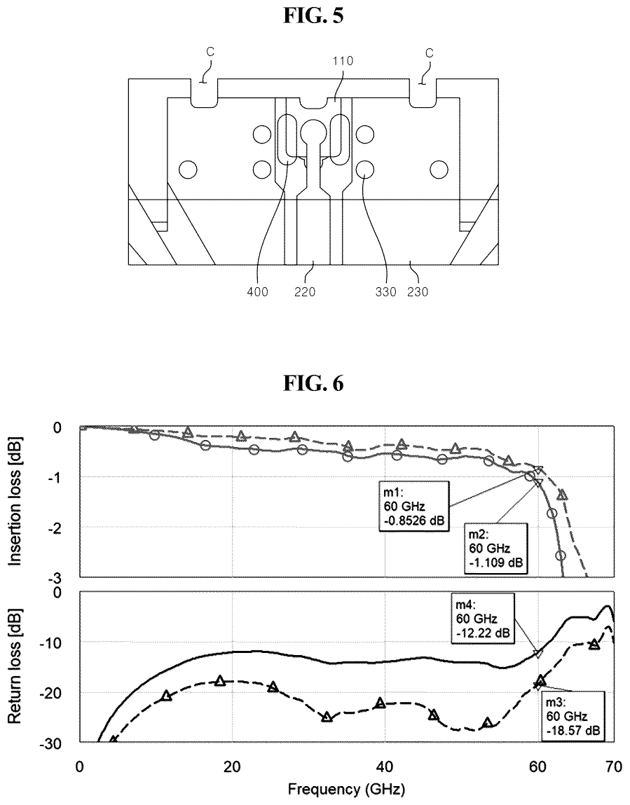

FIGS. 1 and 2 are views showing a semiconductor package having air via according to an embodiment of the present disclosure, FIGS. 3 to 5 are views showing the detailed configuration of a semiconductor package having air via according to an embodiment of the present disclosure, and FIG. 6 is a graph showing a frequency bandwidth of the semiconductor package shown in FIGS. 1 to 5 compared to the conventional cases.

Referring to FIGS. 1 to 6, a semiconductor package 10 having air via according to an embodiment of the present disclosure is surface mounted on the top of a substrate 20 and may include a first dielectric layer 100, a second dielectric layer 200, a third dielectric layer 300, an air via 400, and a heat sink 500.

The semiconductor package 10 having air via according to an embodiment of the present disclosure is surface mounted on the top of a substrate 20, and may include the first dielectric layer 100, the second dielectric layer 200, and the third dielectric layer 300. The air via 400 may be provided vertically in the outer area of a signal line provided in the first dielectric layer 100, the second dielectric layer 200, and the third dielectric layer 300.

At this time, the semiconductor package 10 having air via according to an embodiment of the present disclosure may be provided, for example, as a quad-flat no-lead (QFN) semiconductor package.

The first dielectric layer 100 is the lowest dielectric layer in contact with the substrate 20, and may include a first signal line pad 110, a first ground pad 120, a second ground pad 130, a first ground via 140, a first signal line via 150, a signal line alignment pad 160. The first dielectric layer 100 may be manufactured using, for example, Al2O3, etc. The first dielectric layer 100 made of ceramic material is manufactured by mixing Al2O3 mixed powder to produce a dielectric sheet (green sheet), and through processes such as cutting, so that the first dielectric layer 100 may be surface mounted on the substrate 20 and transmit signals.

The first signal line pad 110 is a pad provided in the lower central area of the first dielectric layer 100 in contact with the substrate 20, and may be formed by screen printing metal paste (e.g., tungsten, molybdenum, copper, niobium, tin, etc.) in a square pattern at the lower center of the first dielectric layer 100.

The first ground pad 120 is a ground pad provided on each side of the first signal line pad 110, adjacent to a castellation cavity C (vertical connection portion of the upper and lower sides) provided vertically on the outer surfaces of the first dielectric layer 100, the second dielectric layer 200, and the third dielectric layer 300. The first ground pad 120 may be formed by screen printing metal paste (e.g., tungsten, molybdenum, copper, niobium, tin, etc.) adjacent to the castellation cavity C in a square pattern on each side of the first signal line pad 110 provided at the bottom of the first dielectric layer 100.

The second ground pad 130 is provided on the top of the first dielectric layer 100 or the bottom of the second dielectric layer 200. The second ground pad 130 is a ground pad provided in the peripheral area excluding the area where the first signal line pad 110 is provided, and is formed in a square pattern on the top of the first dielectric layer 100. The second ground pad 130 is provided in an area outside the area where the first signal line pad 110 is provided, and may be formed by screen printing metal paste (e.g., tungsten, molybdenum, copper, niobium, tin, etc.) to be adjacent to the castellation cavity C.

The first ground via 140 is a via that electrically connects the first ground pad 120 and the second ground pad 130. The first ground via 140 is provided adjacent to the castellation cavity C, with the lower part thereof in contact with the first ground pad 120 and the upper part thereof in contact with the second ground pad 130. The first ground via 140 may be formed by punching the area where the first ground pad 120 or the second ground pad 130 of the first dielectric layer 100 will be provided using, for example, a laser or a mold tool, and then filling the groove with a metal filler (e.g., tungsten, gold, silver, copper, niobium, tin, etc.).

In this case, the first dielectric layer 100 may be manufactured by forming the first ground via 140, then screen printing the first ground pad 120 at the bottom, and screen printing the second ground pad 130 at the top.

The first signal line via 150 is a via that is provided vertically through the first dielectric layer 100 and whose lower part is in contact with the first signal line pad 110. The first signal line via 150 may be formed by punching the area where the first signal line pad 110 of the first dielectric layer 100 will be provided using, for example, a laser or a mold tool, and then filling the groove with a metal filler (e.g., tungsten, gold, silver, copper, niobium, tin, etc.).

The signal line alignment pad 160 is a pad provided on top of the first signal line via 150 and is formed in a circular pattern on the top of the first signal line via 150. The signal line alignment pad 160 may be formed by screen printing metal paste (e.g., tungsten, molybdenum, copper, niobium, tin, etc.) on the upper part of the area where the first signal line via 150 is formed.

In this case, the first dielectric layer 100 may be manufactured by forming the first signal line via 150, then screen printing the first signal line pad 110 at the bottom, and screen printing the signal line alignment pad 160 at the top. The signal line alignment pad 160 may be used as a reference pad for connecting the upper and lower signal line vias when the second dielectric layer 200, which will be described later, is laminated on the first dielectric layer 100.

The second dielectric layer 200 is a dielectric layer stacked on top of the first dielectric layer 100, and may include a second signal line via 210, a second signal line pad 220, a third ground pad 230, and a second ground via 240. The second dielectric layer 200 may be manufactured using, for example, Al2O3, etc. The second dielectric layer 200 made of ceramic material is manufactured by mixing Al2O3 mixed powder to produce a dielectric sheet (green sheet), and through processes such as cutting, so that the second dielectric layer 200 may be stacked on top of the first dielectric layer 100 and transmit signals.

The second signal line via 210 is a via that is provided vertically through the second dielectric layer 200 and whose lower part is in contact with the signal line alignment pad 160. The second signal line via 210 may be formed by punching the area of the second dielectric layer 200 corresponding to the area provided with the signal line alignment pad 160 of the first dielectric layer 100, using, for example, a laser or a mold tool, and then filling the groove with a metal filler (e.g., tungsten, gold, silver, copper, niobium, tin, etc.).

The second signal line pad 220 is a pad provided on top of the second signal line via 210 to transmit signals. The second signal line pad 220 may be formed by screen printing metal paste (e.g., tungsten, molybdenum, copper, niobium, tin, etc.) according to a pattern extending to the inner surface of the second dielectric layer 200 on the upper part of the area where the second signal line via 210 is formed.

The third ground pad 230 is a ground pad provided on each side of the second signal line pad 220, and is formed in a square pattern on the top of the first dielectric layer 100. The third ground pad 230 may be formed by screen printing metal paste (e.g., tungsten, molybdenum, copper, niobium, tin, etc.) in a square pattern to be located in an area outside the area where the second signal line pad 220 is provided and on each side of the area where the air via 400 will be provided. That is, the third ground pad 230 may be formed separately into one side ground pad and the other side ground pad.

The second ground via 240 is a via that electrically connects the second ground pad 130 and the third ground pad 230, and a plurality of second ground vias 240 are provided such that the lower part thereof is in contact with the second ground pad 130 and the upper part thereof is in contact with the third ground pad 230. The second ground via 240 may be formed by punching the area where the third ground pad 230 of the second dielectric layer 200 will be provided using, for example, a laser or a mold tool, and then filling the groove with a metal filler (e.g., tungsten, gold, silver, copper, niobium, tin, etc.).

In this case, the second dielectric layer 200 may be manufactured by forming the second ground via 240 and then screen printing the third ground pad 230 on top.

The third dielectric layer 300 is formed by sequentially stacking a 3-1 dielectric layer 300a and a 3-2 dielectric layer 300b, is a dielectric layer stacked on top of the second dielectric layer 200, and may include a 4-1 ground pad 310, a 4-2 ground pad 320, and a third ground via 330. The third dielectric layer 300 may be manufactured using, for example, Al2O3, etc. The third dielectric layer 300 made of ceramic material is manufactured by mixing Al2O3 mixed powder to produce a dielectric sheet (green sheet), and through processes such as cutting, so that the third dielectric layer 300 may be stacked on top of the second dielectric layer 200 and transmit signals.

The 4-1 ground pad 310 is a ground pad provided between the 3-1 dielectric layer 300a and the 3-2 dielectric layer 300b. The 3-2 dielectric layer 300b is stacked on top of the 3-1 dielectric layer 300a, and the 4-1 ground pad 310 may be formed by screen printing metal paste (e.g., tungsten, molybdenum, copper, niobium, tin, etc.) in a square pattern on the top of the 3-1 dielectric layer 300a.

The 4-2 ground pad 320 is a ground pad provided on the top of the third dielectric layer 300, and may be formed by screen printing metal paste (e.g., tungsten, molybdenum, copper, niobium, tin, etc.) in a square pattern on the top of the 3-2 dielectric layer 300b stacked on top of the 3-1 dielectric layer 300a.

The 4-2 ground pad 320 serves as a ground plane (GP). The 4-2 ground pad 320 not only stabilizes the voltage level by providing an electrical reference point, but also improves the reliability of circuit operation, and may improve the RF performance of the semiconductor package 10 having air via according to an embodiment of the present disclosure by reducing electromagnetic interference (EMI) and electromagnetic radiation (EMC) problems.

The third ground via 330 is a via that vertically penetrates the 4-1 ground pad 310 and electrically connects the third ground pad 230 and the 4-2 ground pad 320. A plurality of the third ground vias 330 are provided such that the lower part thereof is in contact with the third ground pad 230 and the upper part thereof is in contact with the 4-2 ground pad 320. The third ground via 330 may be formed by punching the 3-1 dielectric layer 300a and the 3-2 dielectric layer 300b using, for example, a laser or a mold tool, and then filling the grooves with a metal filler (e.g., tungsten, gold, silver, copper, niobium, tin, etc.).

The third ground via 330 may be formed by stacking the 3-2 dielectric layer 300b by aligning the ground vias on the top of the 3-1 dielectric layer 300a after forming the ground via of the 3-1 dielectric layer 300a and the ground via of the 3-2 dielectric layer 300b.

The air via 400 is provided on each side of the first signal line via 150 and the second signal line via 210 stacked with the signal line alignment pad 160 in between to vertically penetrate the second ground pad 130 and the third ground pad 230, and provided such that the lower part thereof is located in the internal area of the first dielectric layer 100 and the upper part thereof is in contact with the 4-1 ground pad 410. The air via 400, which is formed in a circular or oval shape, for example, means that a via is formed in a dielectric structure and is filled with air rather than metal.

The air via 400 may be punched vertically using, for example, a laser or a mold tool, in the outer areas (i.e., one side and the other side) of the stacked second signal line pad 220, second signal line via 210, signal line alignment pad 160, and first signal line via 150 after the first dielectric layer 100, the second dielectric layer 200, and the 3-1 dielectric layer 300a are stacked. The air via 400 may be punched such that the lower part thereof is located in the internal space of the first dielectric layer 100.

The air via 400 may be formed by punching the corresponding area of the first dielectric layer 100, punching the corresponding area of the second dielectric layer 200, punching the 3-1 dielectric layer 300a, and then aligning individual air via.

Due to the air via 400, dielectric loss may be reduced by removing a dielectric around the signal line, and by adjusting the diameter and size of the air via 400 according to the diameter of the signal line via and the spacing between the signal line vias, etc., the frequency band of the semiconductor package may be increased as well as the performance of the semiconductor package may be improved.

The heat sink 500 is a block provided in contact with the inner surface of the first dielectric layer 100. The heat sink 500 may be provided to dissipate the heat of the semiconductor package 10 having air via according to an embodiment of the present disclosure, extend device life, maintain performance, and protect electronic devices, and may be made of materials such as aluminum, copper, tungsten-copper composite, and ceramic.

The semiconductor package 10 having air via according to an embodiment of the present disclosure as described above may increase semiconductor package performance and frequency band by reducing dielectric loss by removing the dielectric on the transmission line. As shown in FIG. 6, the frequency bandwidth of the semiconductor package 10 is widened compared to the conventional cases, thereby improving the performance of the semiconductor package.

Therefore, according to an embodiment of the present disclosure, by providing an air via vertically in the space between first, second, and third dielectric layers, which are sequentially stacked with a signal line pad and a ground pad, dielectric loss and parasitic capacitance components of semiconductor packages may be reduced, and thus RF loss may be reduced and the frequency bandwidth may be increased, thereby improving package performance.

In the above description, various embodiments of the present disclosure have been presented and explained, but the present disclosure is not necessarily limited thereto, and those skilled in the art to which the present disclosure pertains will easily understand that various substitutions, modifications and changes can be made without departing from the technical spirit of the present disclosure.

What is claimed is:

1. A semiconductor package having air via, the semiconductor package comprising:
a first dielectric layer, a second dielectric layer, and a third dielectric layer that are sequentially stacked;
a signal line provided in the first dielectric layer, the second dielectric layer, and the third dielectric layer;
a ground, and
an air via provided vertically in an outer area of the signal line.

2. The semiconductor package of claim 1, wherein the first dielectric layer comprises:
a first signal line pad provided in a lower central area of the first dielectric layer in contact with a substrate;
a first ground pad provided on each side of the first signal line pad, adjacent to a castellation cavity provided vertically on outer surfaces of the first dielectric layer, the second dielectric layer, and the third dielectric layer;
a second ground pad provided on a top of the first dielectric layer and in a peripheral area excluding an area where the first signal line pad is provided;
a first ground via electrically connecting the first ground pad and the second ground pad;
a first signal line via vertically penetrating the first dielectric layer and having a lower part thereof in contact with the first signal line pad; and
a signal line alignment pad provided on top of the first signal line via.

3. The semiconductor package of claim 2, wherein the second dielectric layer comprises:
a second signal line via vertically penetrating the second dielectric layer and having a lower part thereof in contact with the signal line alignment pad;
a second signal line pad provided on top of the second signal line via to transmit a signal;
a third ground pad provided on each side of the second signal line pad; and
a second ground via electrically connecting the second ground pad and the third ground pad.

4. The semiconductor package of claim 3, wherein the third dielectric layer is a 3-1 dielectric layer and a 3-2 dielectric layer sequentially stacked, and comprises:
a 4-1 ground pad provided between the 3-1 dielectric layer and the 3-2 dielectric layer;
a 4-2 ground pad provided on a top of the third dielectric layer; and
a third ground via vertically penetrating the 4-1 ground pad and electrically connecting the third ground pad and the 4-2 ground pad.

5. The semiconductor package of claim 3, wherein the air via is provided in an area on each side of the first signal line via and the second signal line via stacked with the signal line alignment pad in between by vertically penetrating the second ground pad and the third ground pad, and provided such that a lower part thereof is located in an internal area of the first dielectric layer while an upper part thereof is in contact with the 4-1 ground pad.

6. The semiconductor package of claim 1, further comprising:
a heat sink provided in contact with an inner surface of the first dielectric layer.
